(19) United States
(12) Patent Application Publication
(10) Pub. No.: US 2015/0317203 A1
(43) Pub. Date: Nov. 5, 2015

(54) Code-Based Read Control for Data Storage Devices

(71) Applicant: Hongchao Zhou, Cambridge, MA (US)

(72) Inventor: Hongchao Zhou, Cambridge, MA (US)

(73) Assignee: Hongchao Zhou, Cambridge, MA (US)

(21) Appl. No.: 14/608,130

(22) Filed: Jan. 28, 2015

Related U.S. Application Data
(60) Provisional application No. 61/988,265, filed on May 4, 2014.

(51) Int. Cl. G06F 11/10; H03M 13/00; H03M 13/13

(52) U.S. Cl. CPC G06F 11/1044; H03M 13/13; H03M 13/611

(57) ABSTRACT

A method is introduced for improving the data reliability of a memory device by jointly designing error-correcting codes and the reading process. In this method, simple and efficient error-correcting codes with a constant-composition part are designed for encoding data, and when reading data from memory cells, the reading reference levels may be dynamically adjusted based on the constant-composition information, which reduces the reading latency and improves the reading accuracy.

### CROSS-REFERENCES TO RELATED APPLICATIONS

This application is a non-provisional patent application of U.S. Provisional Application Ser. No. 61/988,265 filed on May 4, 2014, titled “Code-Based Read Control for Data Storage Devices,” which is hereby expressly incorporated by reference in its entirety for all purposes.

### BACKGROUND OF THE INVENTION

This invention relates to data storage devices and methods, more particularly, to techniques of representing and reading data in data storage devices such as flash memories and phase-change memories.

Flash memory is a type of non-volatile data storage technology that can keep data content even without power supply. It has been widely used in various products such as main memory, memory cards, USB flash drives, solid-state drives for general storage and transfer of data.

Flash memory stores information with floating-gate transistors that hold electric charges, which correspond to the threshold voltages of the cells. In traditional single-level cell (SLC) devices, each cell has two voltage states and, hence, it can store a single bit. In order to improve the capacity of flash memories, multi-level cell (MLC) devices have been developed to store more than one bit per cell. For example, with 4 threshold voltage states, each cell can store 2 bits; and with 8 threshold voltage states, each cell can store 3 bits. In general, a MLC device with q voltage states can store log₂ q bits per cell.

The drift of cell threshold voltages, caused by charge leakage, is a key factor that determines the capacity and reliability of flash memories. A main physical mechanism behind the charge leakage in flash memories is the stress-induced leakage current (SILC), which critically depends on the oxide conduction regime. The leakage current increases as the voltage level of a cell increases, and hence a higher voltage level usually has a larger voltage change (offset) than a lower voltage level. For example, experiments based on 3×-nm MLC NAND flash memories show that errors introduced by charge leakage are dominant among all types of errors. Another challenge for data reliability in flash memories is that they can store data only for a finite number of program-erase (P/E) cycles. For example, some present SLC NAND flash is rated at about 100 k P/E cycles; some 2-bit MLC NAND flash is rated at about 1-10 k P/E cycles. As the number of P/E cycles of a cell increases, the charge leakage problem becomes more serious in flash memories.

The cell threshold voltages in flash memories change over time due to the drift effect. When reading data from a plurality of memory cells, the threshold voltage distribution of each state is typically unknown, because it depends on many untracked parameters, including the time duration that the data has been stored, the program/erase cycles of the cells, the surrounding temperature, etc.

The drift behavior can also be observed in other nonvolatile data storage devices, such as phase change memories, which is among the most promising technologies for future replacement of standard floating-gate based flash memory. A phase-change cell is a resistor of chalcogenide material, whose resistance depends on the phase state—either amorphous or crystalline. Amorphous state has a resistance several orders of magnitude higher than crystalline state. The resistance drift is the major reliability concern in MLC phase-change memories. It is a result of two physical mechanisms: structural relaxation (SR) and crystallization of the amorphous material.

Conventional approaches, with fixed reference levels, are not efficient for correcting errors introduced by the drift effect. Given a memory device with q states, conventional approaches divide the cell threshold voltages into q intervals based on q−1 fixed reference levels, and the logical data stored in a cell is determined by the interval in which the cell threshold voltage lies. Due to the drift effect, the cell threshold voltages are prone to crossing the reference levels, causing a large number of asymmetric errors. The problem gets more and more serious when the number of levels q becomes larger, resulting in smaller intervals.

Recently, several methods are proposed to dynamically find the reference levels that can reduce the number of errors. For example, one method is to estimate the statistics of the cell threshold voltages using many more reference levels, and then determine a set of reference levels for reading data based on the estimated statistics. Another example is to try different sets of reference levels and decode all the resulting words until there is no error after decoding. However, these methods usually require too many attempts (reference levels) and sometime require decoding multiple times. Although the data reliability can be improved with the prior art methods, they generally result in significant increase in latency and energy cost for reading data.

### SUMMARY OF THE INVENTION

The present invention provides a data representation and reading method for data storage devices. It incorporates the process of reading control (finding a good set of reference levels) with the design of error-correcting codes.

The present invention does not rely on any models of the cell voltage distributions or the cell voltage statistics. Compared with the prior art approaches, the present invention can further improve the data reliability of memory devices and reduce the latency and the computational cost (or energy cost) for reading data.

According to the present invention there is provided a method of encoding and reading data in memory devices, including the steps of: (a) encoding the data such that, for a given set of the programmed cells, the number of cells in each (or some) state and the states above is equal to a specified constant; (b) determining a set of reference levels such that, in the given set of cells, the number of cells having a voltage above each (or some) reference level is equal to or close to one of the specified constants; (c) reading data based on this set of reference levels and decoding it.

In some embodiments, the number of cell levels q may be an arbitrary integer that is equal to or larger than 2. The code may be an error-correcting code, namely, it may tolerate a certain level of errors.

In some embodiments, the given set of cells may be all the cells corresponding to the programmed codeword. In other embodiments, the given set of cells may be a subset of the cells corresponding to the programmed codeword.

In some embodiments, there may be one specified constant, or q−1 specified constants. For example, given a set of memory cells in 2-bit MLC, the number of cells in state 2, 3 or 4 may be set to 800; the number of cells in state 3 or 4 may be set to 500; and the number of cells in state 4 may be set to 250.

Furthermore, according to the present invention there is provided a system including: (a) a memory cell array including a plurality of memory cells; (b) a circuitry for programming each memory cell to one of the states and comparing the threshold voltages with at least one reference level; (c) a reading control unit for determining a good set of reference levels; and (d) an error-correcting code (ECC) encoder/decoder for encoding data into a desired form and correcting errors.

According to example embodiments, a method of controlling a reference level may include: counting the number of memory cells having a voltage above a reference level for a given set of programmed cells; deciding whether to reset the reference level and how to reset the reference level based on the difference between the counted number and the respective specified constant.

According to example embodiments, a coding scheme for the ECC encoder/decoder is provided. In this coding scheme, a balanced ECC for MLC is constructed by composing multiple binary balanced ECC. Based on this coding scheme, the number of cells in each state is the same constant among all the cells that correspond to the programmed codeword.

According to example embodiments, another coding scheme for the ECC encoder/decoder is provided. In this coding scheme, a fixed part of each codeword (e.g. the first k bits of each codeword that correspond to data bits) is balanced. Based on this coding scheme, within a subset of cells that correspond to a codeword, the number of cells in each state is the same constant.

### BRIEF DESCRIPTION OF THE DRAWING

The above and other features and advantages of example embodiments will become more apparent by describing in detail example embodiments with reference to the attached drawings.

FIG. 1 is a block diagram illustrating an example of a memory device according to example embodiments;

FIG. 2 illustrates a diagram for explaining a method of determining a reference level according to some embodiments;

FIG. 3 illustrates a flowchart of a method of determining a reference level according to some embodiments;

FIG. 4 illustrates a construction of large-alphabet balanced error-correcting codes;

FIG. 5 illustrates a construction of binary balanced error-correcting codes;

FIG. 6 illustrates a construction of large-alphabet part-balanced error-correcting codes;

FIG. 7 illustrates a construction of large-alphabet balanced or part-balanced error-correcting codes;

FIG. 8 illustrates a flowchart of a method of reading information from memory cells according to some embodiments;

FIG. 9 shows the capacity and data retention time of a method according to the present invention and a method based on fixed reference levels in some simulations.

### DETAILED DESCRIPTION OF THE INVENTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

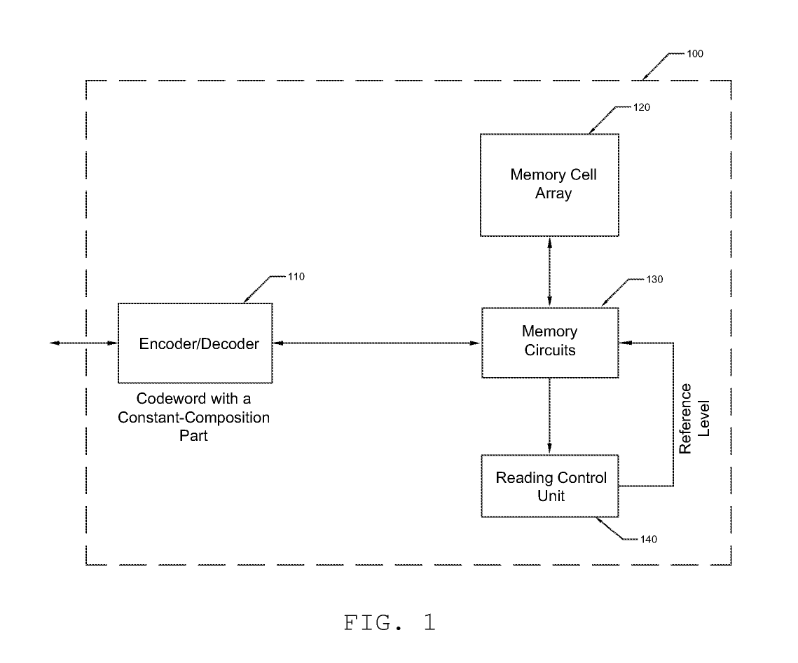

FIG. 1 illustrates a block diagram of a memory device 100 according to some embodiments. The memory device includes an ECC encoder/decoder 110, a memory cell array 120, a memory circuitry 130, and a reading control unit 140. In addition, the ECC encoder/decoder 110 may be included in a memory controller; the memory cell array 120 and the memory circuitry 130 may be included in a memory chip. The reading unit 140 may be implemented with hardware or software, or a combination of them, and it may be included in either a memory controller or a memory chip.

The memory cell array 120 may include a plurality of memory cells. Depending the data stored, the cells may have multiple threshold voltage states. For example, for SLC, each cell has two states, and for 2-bit MLC, each cell has four states. In general, for a memory cell with q states, we call the states as state 1, state 2, . . . , state q, respectively, from low threshold voltage to high threshold voltage. Each state represents a value stored in the respective cell.

The circuitry 130 may write data into memory cells by changing their threshold voltages, i.e., programming them into the respective states. In some embodiments, the circuitry 130 may program a set of memory cells simultaneously, and we refer to such a set of memory cells as a page. For example, a page may include one thousand memory cells. The circuitry 130 may compare the threshold voltages of the cells in a page with at least one reference level for reading data. In some embodiments, the circuitry 130 may compare the threshold voltages of the cells in a page with multiple reference levels simultaneously.

When storing data into a plurality of memory cells, the encoder 110 may map a string of data bits into a codeword that has a constant-composition part, namely, each value appears a fixed number of times in a given part of the codeword or in the whole codeword. Then the memory circuitry 130 writes the codeword into a plurality of memory cells in the memory cell array 120 by programming each cell into one of the q voltage states. Due to the constant-composition property of the codeword, within the set of the programmed cells corresponding to the constant-composition part of the codeword, the number of cells in each state is equal to a pre-specified constant. For example, the memory circuitry 130 may program a codeword into one thousand memory cells, and among the first 800 cells, the number of cells in state 1 is always 150, the number of cells in state 2 is always 250, the number of cells in state 3 is always 200, and the number of cells in state 4 is always 200.

We denote the set of the programmed cells corresponding to the constant-composition part of a codeword as set S. It may consist of all the cells corresponding to a codeword, or a subset of the cells (the cells may be adjacent or not). Furthermore, among the cells in the set S, we use K₁ to denote the number of cells in state 2 or above, K₂ to denote the denote the number of cells in state 3 or above, etc. Then K₁, K₂, . . . are fixed constants, specified by the encoder 110, and also known by the reading control unit 140. These constants may help the reading control unit 140 to find a good set of reference levels.

The threshold voltage distributions of the memory cells in the memory cell array 120 change over time. When reading data from a set of memory cells that store a codeword, the reading control unit 140 counts the number of cells above each of the q−1 reference levels within the given set of cells S. We let R₁ denote the lowest reference level, and the number of cells with a voltage above R₁ in S is N₁; similarly, we let R₂ denote the second lowest reference level, and the number of cells with a voltage above R₂ in S is N₂, etc.

The reading control unit 140 determines whether the current set of reference levels are good or not based on the counted numbers N₁, N₂, etc. For some embodiments, the criterion may be described by

|K₁−N₁|+|K₂−N₂|+ . . . +|K_{q}−N_{q}|≦T,

where |K₁−N₁| is the absolute value of (K₁−N₁), and T is a predetermined threshold. If this criterion is satisfied, it means that the current set of reference levels are good. For some other embodiments, the criterion may be described by

|K₁−N₁|≦T₁,|K₂−N₂|≦T₂, . . .

for a set of predetermined thresholds T₁, T₂, . . . .

If the current set of reference levels satisfy the criterion, the circuitry 130 then reads data based on this set of reference levels and passes the read word to the ECC decoder 110 for error correction or decoding. If the current set of reference levels do not satisfy the criterion, the reading control unit 140 computes and resets at least one reference level, until the criterion is satisfied.

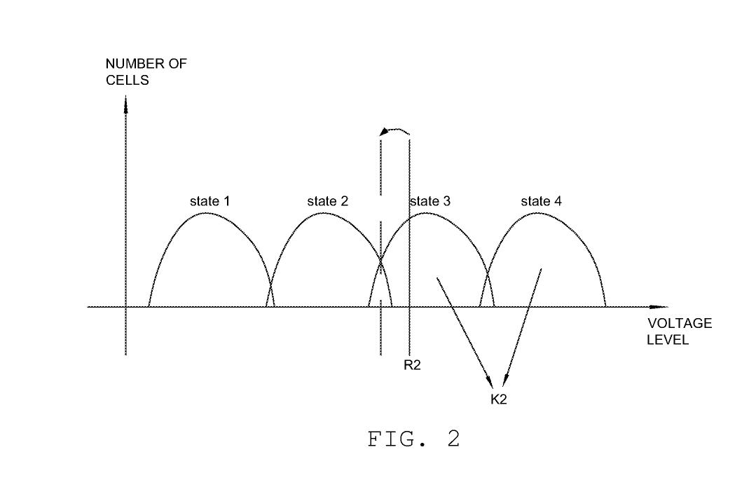

FIG. 2 illustrates a diagram for explaining a method of determining a reference level according to some embodiments. The method may be performed by the reading control unit 140 illustrated in FIG. 1, and it will be explained with 2-bit MLC, which has 4 voltage states.

Referring to FIG. 2, R₂ is the second reference level and it separates state 2 and state 3. In the given cell set 5, K₂ is the total number of cells that are in state 3 or state 4. Let N₂ be the number of cells in S that have a voltage above the reference level R₂. Our goal is to find a reference level R₂ such that the difference between N₂ and K₂ is as small as possible. In fact, such a reference level always yields a performance close to the optimal possible reference level.

Let E₂⁰ be the number of cells in S that are in state 1 or state 2 and with a voltage higher than the reference level R₂. Let E₂¹ be the number of cells in S that are in state 3 or state 4 and with a voltage lower than the reference level R₂. Then

N₂=K₂−E₂¹+E₂⁰.

If N₂=K₂, then E₂⁰=E₂¹. It means that the number of cells with a voltage crossing the reference level R₂ from below is equal to the number of cells with a voltage crossing the reference level R₂ from above. The total number of errors in S introduced by the reference level R₂ is E₂⁰+E₂¹. Assume that there exists an optimal reference level R₂* that can minimize the total number of errors. Then the number of errors in S introduced by R₂* is E₂⁰*+E₂¹*, where E₂⁰* is the number of cells in state 1 or state 2 in S with a voltage higher than R₂*, and E₂¹* is the number of cells in state 3 or state 4 in S with a voltage lower than R₂*. If R₂* is larger than R₂, then E₂¹* is larger than or equal to E₂¹, and in this case,

E₂⁰+E₂¹=2E₂¹≦2E₂¹*≦2(E₂⁰*+E₂¹*).

The same conclusion holds when R₂* is smaller than R₂, showing that the number of errors introduced by R₂ in S is always upper bounded by two times the minimal possible number of errors. Here, we don't have any assumptions about the cell threshold voltage distributions, and this conclusion implies that we can always get a good reference level R₂ by making N₂ as close to K₂ as possible. For example, if the cells in state 2 and state 3 can be fully separated, then the number of errors in S introduced by R₂ is zero.

If N₂ is not equal to K₂, the difference between them, i.e., K₂−N₂, reflects how good the current reference level R₂ is. If the reference level R₂ needs to be reset, the information K₂−N₂ can be used for finding a new reference level. For some embodiments, we may let

R₂(i+1)=R₂(i)+h(K₂−N₂),

where R₂(i) is the current reference level, R₂(i+1) is a new reference level, and h(K₂−N₂) is a function of K₂−N₂, which can be determined based on empirical tests. This function h may be identical or different for the q−1 reference levels.

It has been stated that a new reference level can be determined from the current reference level. But embodiments are not limited thereto. For example, a new reference level may be determined based on multiple reference levels and the respective counted cell numbers.

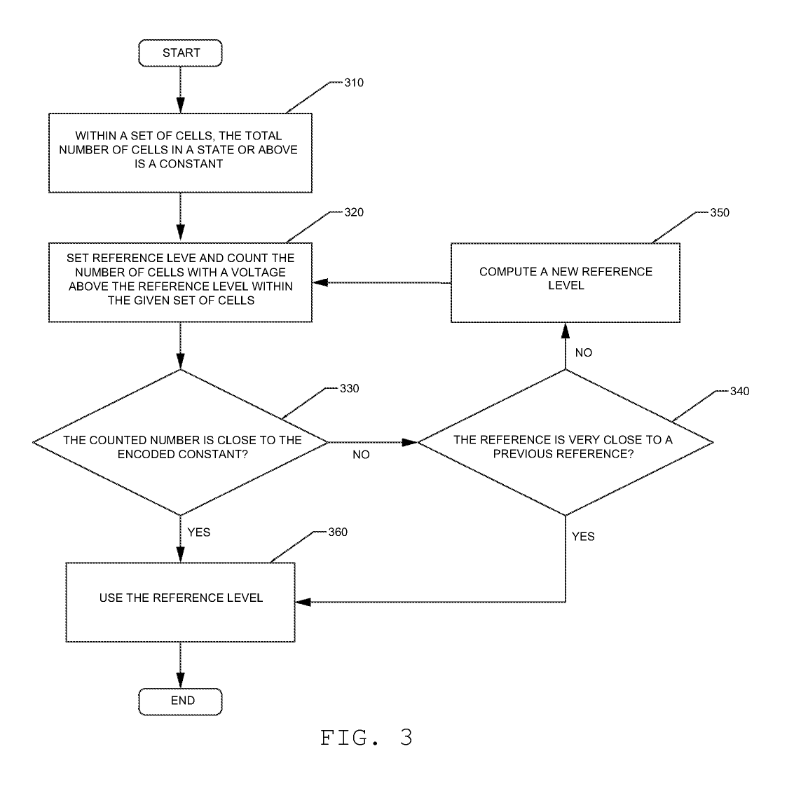

FIG. 3 illustrates a flowchart of a method of determining a reference level according to some embodiments. The method may be performed by the reading control unit 140 illustrated in FIG. 1.

Referring to FIG. 3, when writing data into a memory device, the encoder 110 encodes the data into a codeword such that the number of cells in a state or the states above is a given constant within a set of cells S in operation 310.

When reading data from a plurality of memory cells in the memory cell array 120, the number of cells in the set S with a voltage higher than a predetermined reference level is counted in operation 320. The difference between the countered number and the respective encoded constant is calculated in operation 330. If the difference is smaller than or equal to a predetermined threshold, then the reference level is used for reading data in operation 360. However, the condition is not limited thereto. For example, if the sum of the differences for all the levels is smaller than or equal to a predetermined threshold, then all the reference levels are used for reading data in operation 360. If the difference between the countered number and the respective encoded constant exceeds the predetermined value, the method further checks whether the current reference level is close to one of the previous tried reference levels in operation 340. If the gap is smaller than a threshold value, possibly caused by too many attempts of reference levels, the method goes to operation 360. Otherwise, the method computes a new reference level in operation 350, and returns back to operation 320.

Based on the above method, a reference level can be determined. However, the description is not limited thereto. For some embodiments, the reading control unit 140 may stop trying new reference levels when it has already tried a certain number of times, e.g., 2 times.

For some embodiments, multiple reference levels may be computed jointly or set simultaneously. Based on the determined reference levels, a word is read and passed to the ECC decoder 110 for further processing.

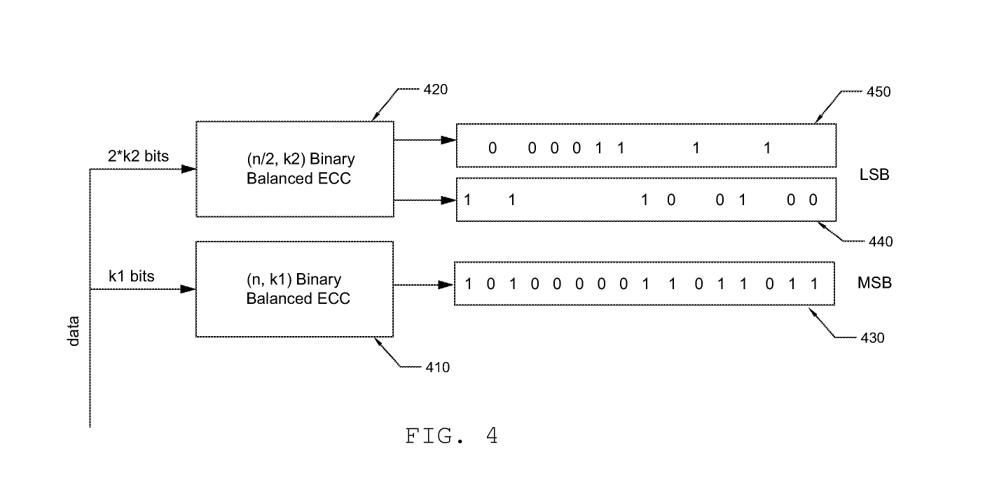

Referring now to FIGS. 4, 5, 6 and 7, they illustrate several code constructions for the ECC encoder/decoder 110. Our objective is to construct practical and efficient error-correcting codes such that every codeword has a constant-composition part, namely, each value appears a fixed number of times in a given part of the codeword or in the entire codeword. In order to maximize the code rate and to simplify the encoding/decoding process, it is preferred that all the values appear an equal number of times. Such a code is called balanced code. One example of a balance code is a binary code with codeword length 1000, in which each codeword has 500 ones and 500 zeros. If all the values appear an equal number of times in a given part of each codeword, then we call such a code a part-balanced code. For example, we may have a part-balanced code such that only the first 500 symbols of each codeword are “balanced.” Compared to balanced codes, part-balanced codes may yield almost the same set of reference levels, and meanwhile, they may be easier to encode and decode, and more efficient for correcting errors.

Referring now to FIG. 4, there is shown a construction of balanced error-correcting codes for MLC. Although the description is focusing on 2-bit MLC, the construction can be applied to any the number of levels q when q is a power of 2.

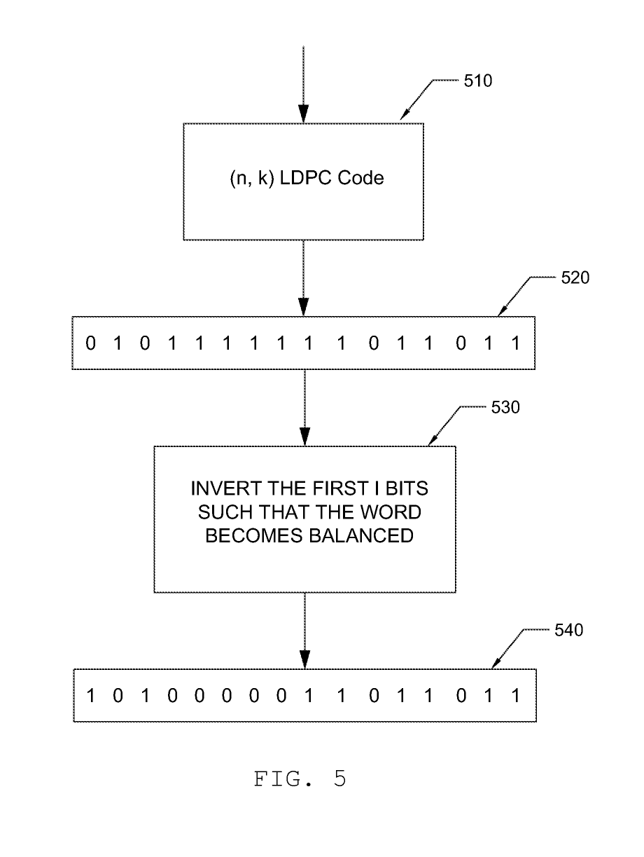

As illustrated in FIG. 4, the construction is a composition of two binary balanced error-correcting codes: (a) an (n, k₁) binary balanced error-correcting code 410, which maps each binary string of length k₁ into a binary balanced word of length n, and (b) an (n/2, k₂) binary balanced error-correcting code, which maps each binary string of length k₂ into a binary balanced word of length n/2. Constructions of binary balanced error-correcting codes will be discussed with reference to FIG. 5, and here we focus on how to use binary balanced error-correcting codes to construct a large-alphabet balanced error-correcting for MLC.

The encoding process is described as follows. Given the data, a binary string of length k₁+2k₂, we use the (n, k₁) binary balanced ECC 410 to encode its first k₁ bits, and use the (n/2, k₂) binary balanced ECC 420 to encode its next k₂ bits and the last k₂ bits. After this, three binary balanced words are obtained: a binary balanced word 430 with length n, and two binary balanced words 440 and 450 with length n/2. We use the word 430 as the most significant bits (MSB) of the final codeword. We combine the word 440 and the word 450 to form the least significant bits (LSB) of the final codeword, where the positions of the bits in the word 440 correspond to the positions of is in the word 430, and the positions of the bits in the word 450 correspond to the positions of 0s in the word 430.

After the encoding process, the encoder 110 sends the codeword, i.e., the MSB sequence and the LSB sequence, to the memory circuitry for programming the memory cells. The memory device 100 maps each bit pair (MSB and LSB) into one of the four voltage states. In particular, it is based on Gray mapping, i.e., 11 is mapped into state 1, 10 is mapped into state 2, 00 is mapped into state 3, and 01 is mapped into state 4. It is easy to check that based on the encoding process illustrated in FIG. 4, among the 16 programmed cells corresponding to the codeword, 4 of them will be programmed to state 1, 4 of them will be programmed to state 2, etc. Hence, the codeword is balanced.

The decoding process of the proposed code construction, still referring to FIG. 4, is described as follows. After reading data from the memory cell array 120, the ECC decoder 110 receives two binary sequences of length n: one MSB sequence and one LSB sequence. The ECC decoder 110 first decodes the MSB sequence based on the decoding algorithm of the (n, k₁) binary balanced ECC 410. During this process, the first k₁ data bits are obtained, and all the errors in the MSB sequence can be corrected if the total number of errors is smaller than a threshold. Then, based on the corrected MSB sequence, the ECC decoder 110 divides the LSB sequence into two binary sequences, each of length n/2. The first sequence consists of the bits in the LSB sequence with positions corresponding to the is in the corrected MSB sequence. The second sequence consists of the bits in the LSB sequence with positions corresponding to the 0s in the corrected MSB sequence. The two sequences of length n/2 can be treated as erroneous versions of the word 440 and the word 450. By decoding the two sequences based on the (n/2, k₂) binary balanced ECC 420, the rest 2k₂ data bits can be obtained. This finishes the decoding process.

In further detail, when reading data from the memory cell array 120, the number of errors in the MSB sequence 430 is approximately equal to the number of cells with an error introduced by the second reference level. The number of errors in the first subsequence of the LSB sequence 440 is approximately equal to the number of cells with an error introduced by the first reference level. The number of errors in the second subsequence of the LSB sequence 450 is approximately equal to the number of cells with an error introduced by the third reference level. For one example of the encoder, we may let the (n, k₁) binary balanced ECC and the (n/2, k₂) binary balanced ECC tolerate the same number of errors t. Given t and n, the dimensions k₁ and k₂ are fixed. However, the selection of the parameters is not limited thereto.

Referring now to FIG. 5, there is shown a construction of binary balanced error-correcting codes. Before introducing this construction, the prior art on binary balanced codes and binary balanced error-correcting codes is briefly described.

Knuth, in 1986, proposed a simple method of constructing binary balanced codes, whose codewords have an equal number of 0s and 1s. See, for example, Knuth, “Efficient balanced codes,” IEEE Trans. Inform. Theory. vol. 32, no. 1, pp. 51-53, 1986. In this method, given an information word of k bits (k is even), the encoder inverts the first I bits (0≦I<k) such that the modified word has an equal number of 0s and 1s. Here, inverting a bit means changing 0 to 1 and changing 1 to 0. Knuth showed that such an integer I always exists. In order to retrieve the original word, this integer I is stored as a short balanced word of length p. Then a codeword consists of a p-bit prefix that stores I and a k-bit modified information word. Knuth's method was later improved and modified by many researchers.

Several constructions of binary balanced error-correcting codes have been studied in literature. Recently, Weber, Immink and Ferreira extent Knuth's method to build binary balanced error-correcting codes. See, for example, Weber, Immink and Ferreira, “Error-correcting balanced Knuth codes,” IEEE Trans. Inform. Theory, vol. 58, no. 1, pp. 82-89, 2012. The idea is to assign different error protection levels to the prefix and the modified information word in Knuth's construction. So the construction is a concatenation of two error-correcting codes with different error-correcting capabilities.

As illustrated in FIG. 5, a new construction of binary balanced error-correcting codes is provided, with advantages in construction simplicity and error-correcting performance. In this construction, the codewords are obtained by balancing the codewords of an LDPC code. We call such a code a balanced LDPC code.

The encoding process of a balanced LDPC code is described as follows: given a binary string of length k, we first encode it with an (n, k) LDPC code 510, and the output is a binary word 520 of length n. Based on Knuth's idea, we can find an integer I (0≦I<n) such that inverting the first I bits of the word 520 results in a word with an equal number of 0s and 1s. Hence, we find this integer I and invert the first I bits of the word 520 in the step 530. This operation results in a balanced word 540, where the number of 0s is equal to the number of 1s. This word 540 is a codeword of the balanced LDPC code.

In the construction, the integer I is not stored in the codewords of a balanced LDPC code. Certain redundancy exists in the codewords of the original LDPC code that enables us to locate I or estimate I with high accuracy. Note that the redundancy of an LDPC code is typically Θ(n) bits, and the information required to represent the integer I is only Θ(log n) bits.

Let y be the received word after transmitting a codeword over a channel. The biggest challenge of decoding y is lacking of the location information about where the inversion happens, i.e., the integer I. A simple idea of decoding a balanced LDPC code is to search all the possibilities for the integer I, and for each possible integer I, we decode the respective received word. The drawback of this decoding method is its high computational complexity, which is about n times the complexity of decoding the original LDPC code.

To reduce the computational complexity, another decoding algorithm is provided, including the steps of: (a) getting an estimated value of the integer I; and (b) decoding the received word y based on the estimated value of the integer I. For some embodiments, the estimated value of the integer I can be computed by finding the minimal integer J that minimizes the Hamming weight of

H(y+1^{J}0^{n-J}),

where H is the sparse parity-check matrix of the original LDPC code, 1^{J}0^{n-J} denotes a run of J bits 1 and n−J bits 0, and (y+1^{J}0^{n-J}) is the word obtained by inverting the first J bits of the word y. In another word, the estimated value of the integer I is an integer that minimizes the weight of the syndrome of the received word. It can be proved that this estimated value I can be computed within a linear time. An intuition is that given H(y+1^{J}0^{n-J}), then H(y+1^{J+1}0^{n-J-1}) can be computed in a constant time by only updating the check nodes that connect to the (J+1)th variable node in the bipartite graph of the LDPC code. Hence, we can compute the weights of all H(y+1^{J}0^{n-J}) iteratively and obtain the estimated value of the integer I in a linear time. Finally, we invert a prefix of the word y based on the estimated value of the integer I, and apply the decoding algorithm of the original LDPC code to get the stored data. This completes the decoding process.

Numerical simulation shows that the balanced LDPC code based on the above decoding method has almost the same error-correcting capacity as the original LDPC code. It means that by paying little price, we can convert an LDPC code into a balanced LDPC code. Meanwhile, according to present invention, the number of errors can be significantly reduced with the help of balanced error-correcting codes.

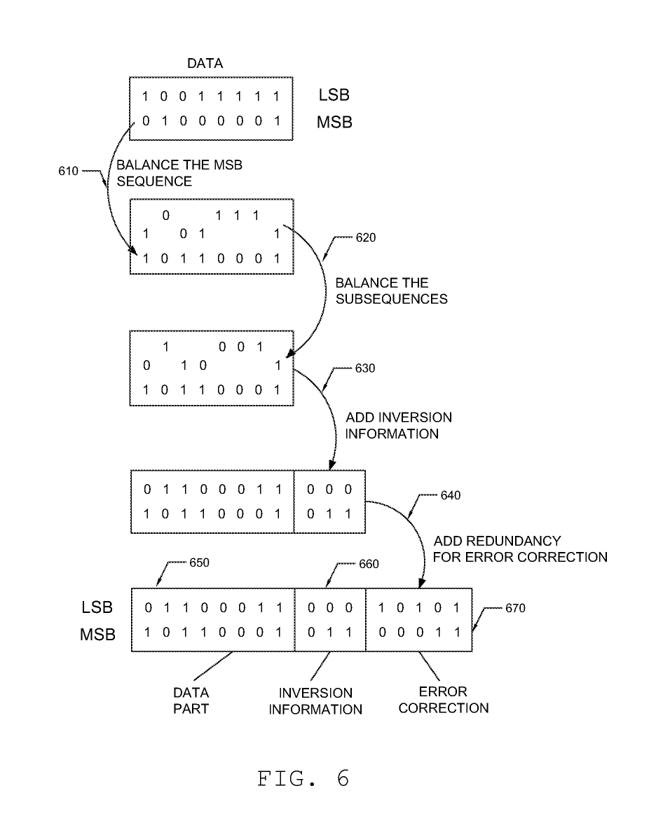

Referring now to FIG. 6, there is shown a construction of part-balanced error-correcting codes for MLC. Although the description is focusing on 2-bit MLC, the construction can be applied to any number of levels q when q is a power of 2. In contrast to balanced error-correcting codes for MLC, it may be much easier and more efficient to construct error-correcting errors where only a part of each codeword is balanced.

The encoding process of the proposed error-correcting code is described as follows. The data to encode is represented by two binary strings, each of length k and corresponds to the MSB and LSB words, respectively. In operation 610, the encoder balances the MSB string. For example, Knuth's idea may be adopted: one can balance a binary string by inverting its first I bits, and such an integer I always exists if the length of the string is even. In operation 610, the encoder inverts the first 4 bits of the MSB string, and as a result, it gets a balanced binary sequence 10110001. Then, based on this balanced binary sequence, the encoder divides the LSB string into two subsequences (with a similar method as shown in FIG. 4), and they are 1011 and 0111, respectively. In operation 620, the encoder further balances the two subsequences using Knuth's idea. By inverting the first 3 bits of 1011, the encoder obtains a balanced subsequence 0101 with two 0s and two 1s. By inverting the first 3 bits of 0111, it obtains another balanced subsequence 1001 with two 0s and two 1s. In order to recover the original data, all the positions where inversions happen should be recorded. So in operation 630, the three integers 4, 3 and 3 are represented by bits and recorded in the codeword. Note that depending on the length of the MSB string and the length of the LSB subsequences, the integer 4 is represented by 3 bits (it has 8 possibilities), and both the integers 3 are represented by 2 bits. In operation 640, we encode all the existing bits based on a systematic error-correcting code, such as a Hamming code, a BCH code, an LDPC code, or a Reed-Solomon code. During this step, all the existing bits 650 and 660 remain changed and new redundant bits 670 are added. This finishes the encoding process.

According to this encoding process, each codeword includes three parts: the data part 650, the inversion-information part 660, and the error-correction part 670, as shown in FIG. 6. It can be seen that the data part 650 is balanced: within the cells corresponding to the data part 650, the number of the cells in each state is a constant, which is identical for all the states. For example, in FIG. 6, the data part 650 has 2 cells in state 1, 2 cells in state 2, etc. The part 660 for storing the inversion information is much shorter than the data part 650. The reason is that given a binary string of length k, there are at most k possible values for the inversion position. Hence, this position can be represented by at most log₂ k+1 bits. The error-correction part 670 is longer than the inversion-information part 660. Here, all the bits in the data part 650 and the inversion-information part 660 may be treated as information bits, and a systematic error-correcting code is applied to generate the redundant bits written into the error-correction part 670.

The decoding process is the inverse of the encoding process. First, the decoder corrects all the errors in the received word based on the redundant bits in the error-correction part 670. After the error correction operation, the decoder may check whether the data part is balanced. If the data part is balanced, it means that the error correction is successful; otherwise, there is a decoding failure. From this point, the property that the data part is balanced can be used for error detection. In the next step, the decoder reads the inversion information from the part 660, and based on which, it inverts the data part back to the original bit strings. This finishes the decoding process.

Let's further study some properties of the proposed code construction. In practical memory systems, almost all the cell errors happen between adjacent states, e.g., when a cell in state 3 has an error, it is most likely that the cell is read as state 2 or state 4, rather than state 1. Assume that all the cell errors in a memory system are this type of local errors, then the proposed code construction can correct t cell errors if and only if the underlying error-correcting code can correct t bit errors.

In the proposed construction, the whole data part 650 is balanced. However, the construction is not limited thereto. For example, only a fraction of the data part 650 may be balanced. There is a certain tradeoff: as the length of the balanced part in a codeword decreases, the quality of the estimated reference levels may be reduced, while the reading latency and cost may be improved.

Based on the above code construction, the bits in the MSB sequence may have a different probability of having errors from the bits in the LSB sequence. Assume that for each cell the probability of having an error is p. If the cell errors only happen between adjacent states and all the reference levels have the same probability of introducing errors, then given each reference level, the probability for a cell to have an error caused by this reference level is p/3 for 2-bit MLC. In this case, the probability for a bit in the MSB sequence to have an error is p/3, and the probability for a bit in the LSB sequence to have an error is 2p/3. This information may be used to improve the decoding performance.

For some embodiments, an LDPC code may be used as the underlying error-correcting code. A well-known decoding algorithm for an LDPC code is the belief-propagation algorithm. The input to the belief-propagation algorithm is the log-likelihood ratio (LLR), L(xᵢ), which is defined by

L(xᵢ)=log [P(xᵢ=0|yᵢ)/P(xᵢ=1|yᵢ)]

where xᵢ is the ith bit of the transmitted codeword and yᵢ is the corresponding channel output. According to this definition, if xᵢ is a bit in the MSB sequence, then L(xᵢ)=log((1−p/3)/(p/3)) if yᵢ=1 is received, and L(xᵢ)=−log((1−p/3)/(p/3)) if yᵢ=0 is received. If xᵢ is a bit in the LSB sequence, then L(xᵢ)=log((1−2p/3)/(2p/3)) if yᵢ=1 is received, and L(xᵢ)=−log((1−2p/3)/(2p/3)) if yᵢ=0 is received. Here, the probability p can be estimated based on empirical data.

For some embodiments, the memory device may read data with more than q−1 reference levels, and soft decoding may be used for correcting errors. In this case, the constants K₁, K₂, . . . can be used to improve the performance of decoding. Assume that the voltage of a cell is between two neighboring reference levels R_{A} and R_{B}. The number of cells with a voltage above R_{A} is N_{A}, and the number of cells with a voltage above R_{B} is N_{B}. The probability of each bit stored in the cell (with a voltage between R_{A} and N_{B}) may be written as a function of N_{A}, N_{B} and the constants K₁, K₂, . . . . For example, if both N_{A} and N_{B} are much larger than K₂ in 2-bit MLC, then the probability for the most significant bit stored in the cell having an error is very small.

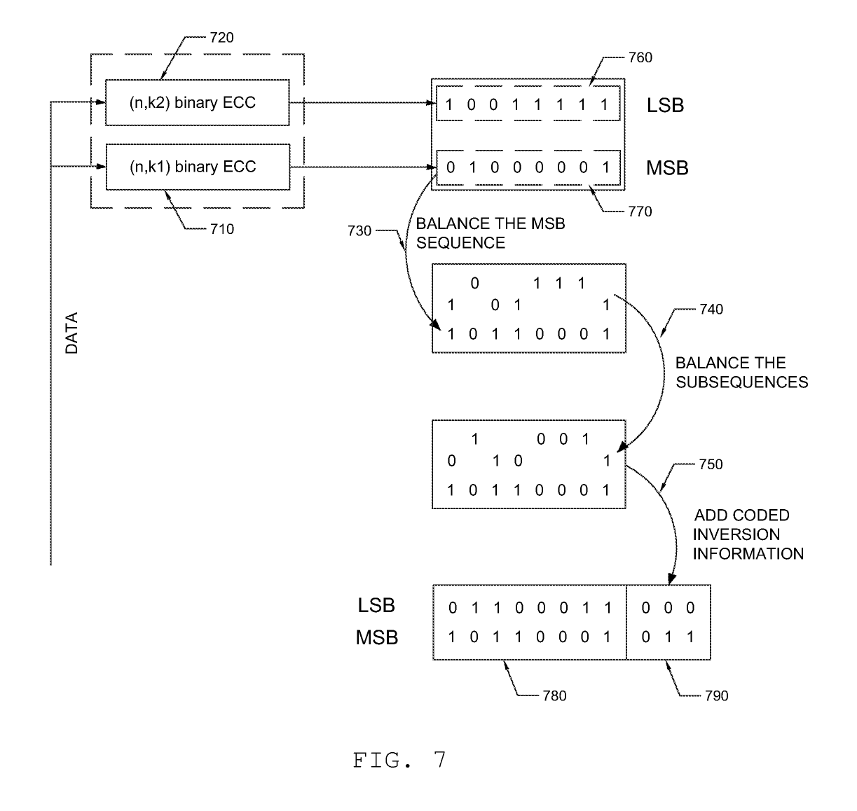

Referring now to FIG. 7, there is shown another construction of balanced or part-balanced error-correcting codes for MLC. Although the description focuses on 2-bit MLC, the construction can be applied to any number of levels q when q is a power of 2.

The encoding process, as illustrated in FIG. 7, is described as follows. Given the data, a binary string of length k₁+k₂, we use a (n, k₁) binary ECC to encode its first k₁ bits, and use a (n, k₂) binary ECC to encode its last k₂ bits, in operations 710 and 720, respectively. After this, two binary strings are obtained: a binary MSB string 770 and a binary LSB string 760. In operation 730, the encoder balances the MSB string 770. For one example, the Knuth's idea may be adopted: one can balance a binary string by inverting its first I bits, and such an integer I always exists if the length of the string is even. In operation 730, the encoder inverts the first 4 bits of the MSB string 770, and as a result, it gets a balanced binary sequence: 10110001. Then, based on this balanced binary sequence, the encoder divides the LBS string 760 into two subsequences, and they are 1011 and 0111, respectively. In operation 740, the encoder further balances the two subsequences. By inverting the first 3 bits of 1011, the encoder obtains a balanced subsequence 0101 with two 0s and two 1s. By inverting the first 3 bits of 0111, it obtains a balanced subsequence 1001 with two 0s and two 1s. In order to recover the original data, all the positions where inversions happen should be recorded. So in operation 750, the three integers 4, 3 and 3 are encoded with a short error-correcting code (balanced or not balanced), as a part of the final codeword. The final codeword consists of two parts: the encoded data part 780 and the encoded inversion-information part 790.

The decoding process is the inverse of the encoding process. The decoder first retrieves the inversion information by decoding the inversion-information part 790. Based on the inversion information, the decoder inverts the first 4 bits of the MSB sequence and decodes it with the (n, k₁) binary ECC. Then based on the corrected MSB sequence, the decoder divides the LSB sequence into two binary subsequences, each of length n/2, corresponding to positions of the 0s or is in the corrected MSB sequence, respectively. Based on the inversion information, the decoder inverts the first 3 bits of the first subsequence, and inverts the first 3 bits of the second subsequence. As a result, by combining the two inverted subsequences, we get an inverted LSB sequence. By decoding the inverted LSB sequence based on the (n, k₂) binary ECC, the rest k₂ data bits can be obtained. This finishes the decoding process.

For one example of the encoder, we may let the (n, k₁) binary ECC tolerate t errors, and let the (n, k₂) binary ECC tolerate 2t errors, for some pre-specified number t. Given t and n, the dimensions k₁ and k₂ are fixed. However, the selection of the parameters is not limited thereto. For some embodiments, a single (2n, k₃) binary ECC may be used to replace the (n, k₁) binary ECC and the (n, k₂) binary ECC, and the drawback is that, during decoding, the errors in MSB sequence may affect the way of dividing the LSB sequence into two subsequences, which may introduce additional errors.

The code constructions illustrated in FIGS. 4 to 7 may be used in the ECC encoder/decoder 110, but embodiments are not limited thereto. The applications of these constructions are also not limited to non-volatile memory devices. For example, they may also be used in optical disc recording devices, communications with wireless fading channels, and optical communications, where the channel output may encounter an unknown offset/gain.

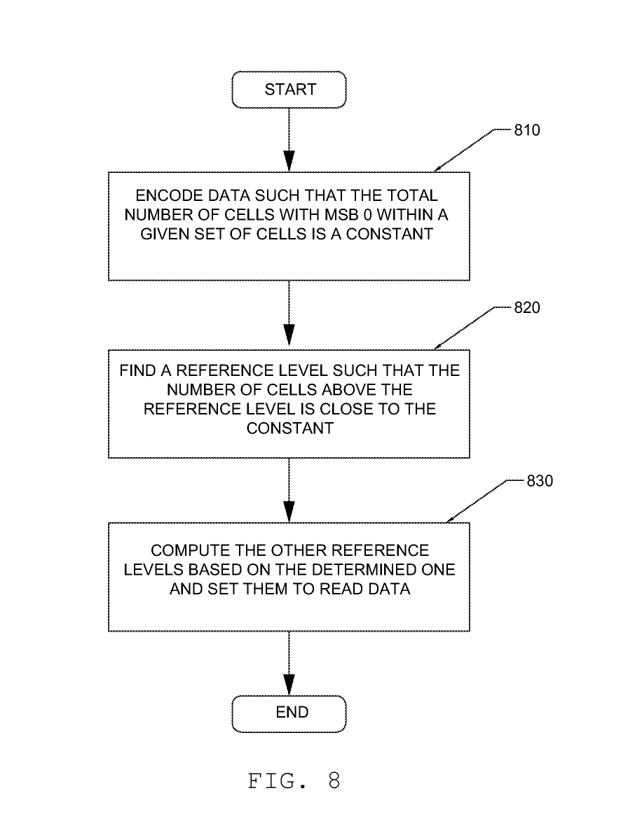

FIG. 8 illustrates of a flowchart of a method of reading information from memory cells according to some other example embodiments. In operation 810, the ECC encoder 110 encodes data such that the number of 0s in a given part of the encoded MSB sequence is a constant, denoted by K. Here, a MSB 0 corresponds to state 3 or state 4 in 2-bit MLC. As a result, within a given set of cells S, the number of cells in state 3 or state 4 is a constant K. When reading data from memory cells, the reading control unit 140 determines a reference level such that the number of cells in a given set S with a voltage above the reference level is close to K. Note that this reference level may be determined with a few iterations, as illustrated in FIG. 3. This reference level can be used as an estimation of the drift effect, since the more it departs from the original level, the more serious the drift is likely to be. Based on this determined reference level, in operation 830, the reading control unit 140 further determines the other reference levels based on some models of memory channels.

For one example, the voltage distributions of memory cells may be modeled as a function of data retention time. Then, based on a determined reference level, the data retention time may be estimated. Furthermore, the reading control unit 140 may compute the other reference levels according to the memory model and the estimated data retention time.

One example of error-correcting codes that may be used in the method is similar to the one illustrated in FIG. 6. However, we don't need to balance the LSB subsequences, and hence the operation 620 can be removed. Another example of error-correcting codes that may be used in the method is to modify the one illustrated in FIG. 4. In this case, the (n/2, k₂) binary balanced error-correcting code 420 may be replaced by an (n, k₃) binary error-correcting code.

In the above examples, the number of cells in state 3 or state 4 within a given set of cells S is a fixed constant, but it is not limited thereto. For example, only the number of cells in state 4 within a given set of cells may be a fixed constant.

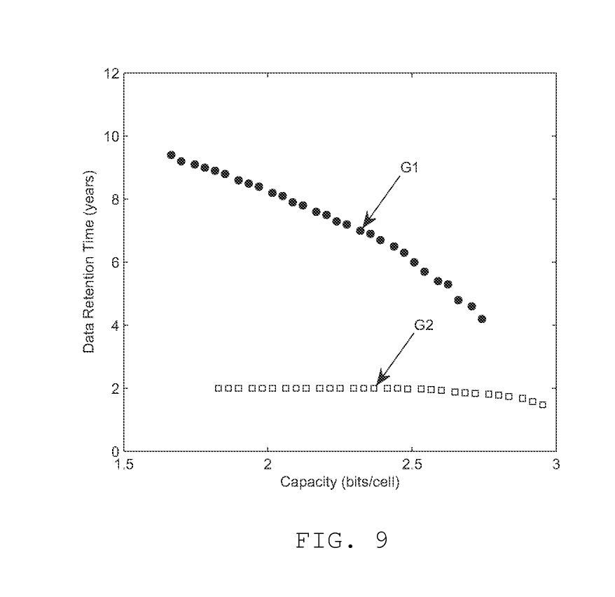

Referring now to FIG. 9, there is shown the simulated performance of a method according to the present invention and a method based on fixed reference levels for a 3-bit MLC memory (with 8 states). In the simulations, the change of the cell threshold voltages is modeled as a dynamic process with both the charge leakage and the reading/programming disturbances.

There are two metrics for measuring the performance of a method: (a) the capacity, i.e., the number of data bits that can be stored per cell; and (b) the data retention time, i.e., the maximum time duration that data can be stored in a block with a negligible error probability. In practical memory systems, it may be expected to maximize the capacity such that the data retention time is larger than a threshold, e.g., 5 years.

In FIG. 9, the capacities and data retention times of both the methods are plotted. The black dots G1 show the performance of the proposed method, and the white squares G2 show the performance of the method with fixed reference levels, based on error-correcting codes of different parameters. FIG. 9 shows that with the same capacity, the proposed method can significantly prolong the data retention time of the memory devices. On the other hand, the method with fixed reference levels may not achieve a required data retention time for the 3-bit MLC, say 4 years. Hence, in this case, we may have to use 2-bit MLC instead of 3-bit MLC when using the method with fixed reference levels. As a comparison, the proposed method can achieve the 4-year data retention time for 3-bit MLC. In a sense, given a specified data retention time, the proposed method can improve the capacity of MLC, either by increasing the number of states or reducing the amount of redundancy.

The advantages of the present invention include, without limitation, that it can significantly improve the data reliability or the capacity of nonvolatile memory systems by dynamically determining the reference levels with the help of code design. Further, the proposed error-correcting codes are efficient and very easy to encode and decode, and they can be easily implemented in the current memory systems. In accordance with embodiments, the computation and time cost for determining the reference levels is reduced, and the quality of the determined reference levels is improved.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

What is claimed:

1. A data storage device comprising:
an encoder configured to map stored data to the discrete levels of a plurality of cells, such that, among this set of cells or a given subset of the cells, the number of cells above a (or each) discrete level is predetermined; and
a reading control unit configured to assign reference voltages for a plurality of cells, such that, among this set of cells or the given subset of the cells, the number of cells having a threshold voltage above the (or each) assigned reference voltage is equal to or close to the predetermined value.

2. The data storage device of claim 1, wherein the reading control unit is configured to:
read the threshold voltages of a plurality of cells; and
count the number of cells having a threshold voltages above the assigned reference voltage(s) for a given set of cells; and
determine and assign a new reference voltage if the counted number is not equal or close to the predetermined value.

3. The data storage device of claim 1, wherein the reading control unit is configured to determine new reference voltages based on the old reference voltages, the numbers of cells having a threshold voltage above some old reference voltages for a given set of cells, and the predetermined values.

4. The data storage device of claim 1, wherein the reading control unit is configured to determine the state of a cell of the plurality of cells by comparing the read threshold voltage of the cell to at least one of the newly assigned reference voltages.

5. A data storage device as in claim 1, wherein the encoder is configured to map data to a q-ary codeword with a constant-composition part, namely, for a fixed part of the codeword, each symbol appears a constant number of times.

6. A data storage device as in claim 1, wherein the encoder maps data to the discrete levels of a plurality of cells according to a q-ary balanced error-correcting code, which is constructed as a composition of log₂ q binary balanced error-correcting codes including:
an (n, k₁) binary balanced error-correcting code, which maps each binary string of length k₁ into a binary balanced word of length n; and
an (n/2, k₂) binary balanced error-correcting code, which maps each binary string of length k₂ into a binary balanced word of length n/2; etc.

7. The system as in claim 6, further comprising:
mapping a data string to multiple binary balanced codewords: one binary balanced codeword of length n, two binary balanced codewords of length n/2, and so on; and
combining all the binary balanced codewords to form a q-ary balanced codeword: e.g., when q=4, the binary balanced codeword of length n is used as the most significant bits (MSB) of the final codeword, the two binary balanced codewords of length n/2 are used as the least significant bits (LSB), with positions correspond to the most significant 1s and the most significant 0s respectively.

8. The system as in claim 6, wherein an (n, k) binary balanced error-correcting code is constructed by:
mapping a binary data string of length k to a binary word of length n with an (n, k) LPDC code; and
inverting the first I bits of the resulting word such that the number of 0s is equal to the number of 1s.

9. The system as in claim 8, wherein the decoding algorithm comprises:
getting an estimated value of the integer I, e.g., the minimal integer I that minimize the Hamming weight of the syndrome; and
decoding the received word y based on the estimated value of the integer I.

10. A data storage device as in claim 1, wherein the encoder maps data to the discrete levels of a plurality of cells according to a q-ary part-balanced error-correcting code, comprising:
writing a binary string as a q-ary word of length k; and
mapping the q-ary word of length k into a q-ary part-balanced word, where each symbol appears the same number of times in the prefix of length k; and
encoding the q-ary part-balanced word with a systematic error-correcting code, such as a Hamming code, a BCH code, an LDPC code, or a Reed-Solomon code.

11. The system as in claim 10, wherein each codeword includes three parts:
the data part, where each symbol appears the same number of times; and
the inversion-information part, which records the inversion information for balancing the data part; and
the error-correction part, which provides extra redundancy for correcting symbol errors.

12. The system as in claim 10, wherein the decoding algorithm comprises:
correcting all the errors in the received word based on the redundant bits in the error-correction part; and
reading the inversion information from the inversion-information part; and
inverting the data part back to the original bit strings based on the inversion information.

13. A data storage device as in claim 1, wherein the encoder maps data to the discrete levels of a plurality of cells according to a q-ary part-balanced error-correcting code, comprising:
mapping a binary data string to log₂ q binary codewords of length n based on log₂ q binary error-correcting codes; and
combining the log₂ q binary codewords of length n to form a q-ary codeword of length n; and
mapping the q-ary word of length n into a q-ary part-balanced word, where each symbol appears the same number of times in the prefix of length n.

14. The system as in claim 13, wherein the decoding algorithm comprises:
retrieving the inversion information by decoding the inversion-information part; and
processing the first n symbols based on the inversion information; and
decomposing the first n symbols into log₂ q binary words; and
correcting errors in the log₂ q binary words.

15. A method comprising:
encoding the data such that, for a given set of the programmed cells, the number of cells in each (or some) state and the states above is equal to a specified constant; and
determining a set of reference voltages such that, in the given set of cells, the number of cells having a voltage above each (or some) reference voltage is equal to or close to one of the specified constants; and
reading data based on this set of reference voltages and decoding data.

16. The method of claim 15 further comprising adjusting the reference voltages based on the old reference voltages, the specified constants, and the number of cells having a threshold voltage above each old reference voltage.

17. The method as in claim 15, wherein the data is encoded into a codeword that has a constant-composition part, namely, for a given part of the codeword, each symbol appears a constant number of times, and then, the codeword is written into a plurality of cells whose discrete levels are specified by the symbols of the codeword.
